(19) United States
(12) Patent Application Publication
(10) Pub. No.: US 2011/0101420 A1
(43) Pub. Date: May 5, 2011

(54) INCREASING FULL WELL CAPACITY OF A PHOTODIODE USED IN DIGITAL PHOTOGRAPHY

(76) Inventor: Pratik Patel, Santa Clara, CA (US)

(21) Appl. No.: 12/610,307

(22) Filed: Oct. 31, 2009

(51) Int. Cl. H01L 27/148; H01L 21/00

(52) U.S. Cl. 257/225; 438/75; 257/E27.122; 257/E21.001

(57) ABSTRACT

A CMOS pixel circuit and timing for use in digital photography where the photodiode has increased full well. The circuit includes the photodiode, a reset transistor, a first transfer gate to move a charge from the photodiode to a floating diffusion node, a source follower transistor, a row select transistor, a second transfer gate located between the photodiode and the first transfer, and a capacitor located between the first and second transfer gates.

### BACKGROUND OF THE INVENTION

1. Field of the Invention

The present invention relates generally to an optical sensor that converts incident light of a received image into electrical signals for use in digital photography and, more specifically, to increasing the storage capacity, the Full Well, of the photodiode used in digital photography.

2. Description of Related Art

In digital photography an image sensor is used to convert a received light image into electrical signals. The image sensor normally consists of a plurality of light detecting elements, where each element generates an electrical signal that relates directly to the intensity of light that falls on that element for the given exposure time. The electrical signals are then used to generate a corresponding image on a display screen.

One very common type of image sensor is an integrated circuit that uses semiconductor devices such as a photodiode as a light detecting element and CMOS circuitry to read out electrical signal where the magnitude of the signal generated is related to the intensity of light that falls on the photodiode.

In current CMOS image sensors, photodiodes are used to generate a charge (electrons) based on the light intensity during an integration time (the time interval when light is being received) and stores the generated charge. The charge, in the form of electrons is then transferred to a floating diffusion node where it is converted to a voltage which is fed to a read out signal chain and finally stored as data for that particular pixel. Based on such pixel data from all pixels of sensors and pixels located on the sensor, a digital image is created which is used in digital photography.

The photodiode, which generates an electrical charge based on incident light, also stores it. This storage capacity which is known as Full Well capacity is very important for dynamic range. Full well capacity relates to the ability of the circuit to capture an image having dark and bright objects at the same time.

More specifically, full well capacity is defined as the amount of charge an individual pixel can hold before saturating. Thus, saturation must be avoided because it results in image smearing which is caused by blooming.

What is needed is a circuit for digital photography that increases the full well capacity of the photodiode.

### SUMMARY OF THE INVENTION

In an exemplary embodiment of the present invention, there is disclosed a CMOS pixel circuit and readout timing concept for use in digital photography where the photodiode has increased full well. The circuit includes a photodiode, a reset transistor, a first transfer gate to move a charge to a floating diffusion node, a source follower transistor, a row select transistor, a second transfer gate located between the photodiode and the first transfer, and a capacitor located between the first and second transfer gates. The capacitor can be of any type, size or shape including but not limited to PN junction capacitance, MOS cap, Poly to poly cap etc. The capacitor is for extra storage for the charge generated by the photodiode during an integration period.

The foregoing has outlined, rather broadly, the preferred feature of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention and that such other structures do not depart from the spirit and scope of the invention in its broadest form.

### BRIEF DESCRIPTION OF THE DRAWINGS

Other aspects, features, and advantages of the present invention will become more fully apparent from the following detailed description, the appended claim, and the accompanying drawings in which similar elements are given similar reference numerals.

FIG. 1 is a schematic diagram of a prior art four transistor CMOS pixel circuit for use in digital photography;

FIG. 2 is a schematic diagram of an embodiment of the invention for providing a fifth transistor and a capacitor to the four transistor CMOS pixel circuit for use in digital photography to obtain increased photodiode Full Well in accordance with the principles of the invention;

FIG. 3 shows read out sequence of rows of interest in a frame; and

FIG. 4 is a timing diagram for the circuit of FIG. 2 in accordance with the principles of the invention.

### DESCRIPTION OF THE PREFERRED EMBODIMENT

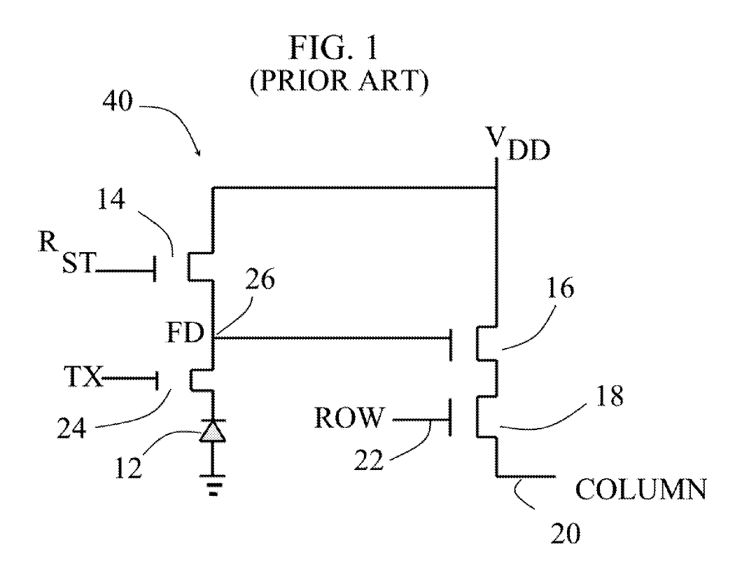

Referring to FIG. 1, there is shown a schematic diagram of a prior art four transistor CMOS pixel circuit 40 for use in digital photography. The basic four transistor pixel architecture consists of a photodiode 12, a reset transistor 14, a transfer gate 24 to move a charge from the photodiode to a floating diffusion sense node 26, a source follower transistor 16, and a row select transistor 18. As shown in FIG. 1, the four transistor circuit includes transistors 14, 16, 18, transfer transistor 24 and a floating diffusion (FD) node 26. With this embodiment, when the Reset Gate and Transfer Gate are turned on simultaneously the pixel is reset which connects the floating diffusion 26 and the photodiode 12 to voltage Vdd. The transfer gate 24 is now turned off which disconnects the photodiode 12 from the voltage source, and the photodiode now integrates receiving light. Upon completion of the integration, the level of the signal is determined. First, the reset transistor is turned on and off to reset the floating diffusion. Then the reset level on the floating diffusion is obtained and stored on the column circuit. Next, the transfer gate is turned on and off to allow the charge on the photodiode to be transferred to the floating diffusion node. Upon completion of the charge transfer, the charge, the photodiode signal level and the floating diffusion reset level, are measured and also stored on the column circuit. The difference between is the photodiode signal level.

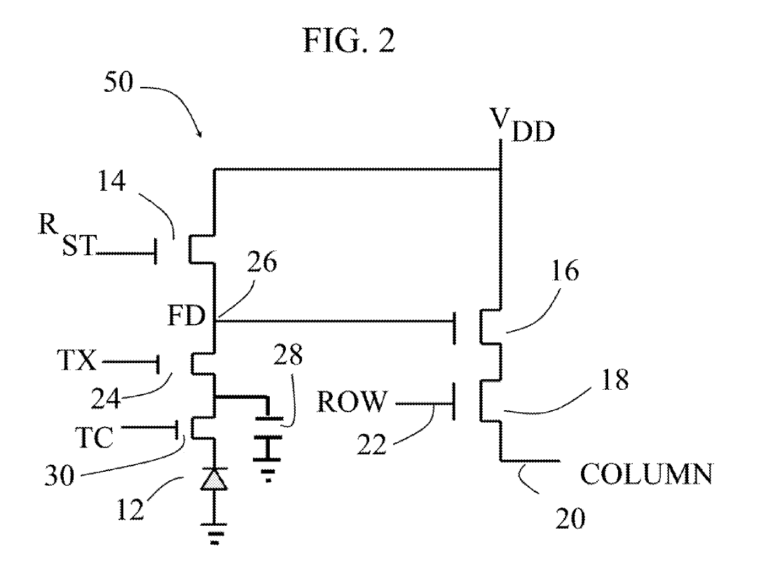

As photodiodes get smaller with smaller pixel size, maintaining/increasing full well is becoming a crucial parameter. In current pixel architectures, the photodiode is used for generating charge and for storing the charge. The photodiode charge storage capacity is limited by its area (the depletion region) for a given doping. One way to improve photodiode limited full well is by separating these tasks, i.e., letting it integrate and generate charge based on light intensity and, at the same time, either simultaneously or in steps during the integration time, store the generated charge to an external capacitor that is located before the transfer gate. This is disclosed in FIG. 2. Referring to FIG. 2, there is shown a schematic diagram 50 of an embodiment of the invention for providing a fifth transistor and a capacitor to the four transistor CMOS pixel circuit for use in digital photography to obtain increased photodiode Full Well in accordance with the principles of the invention.

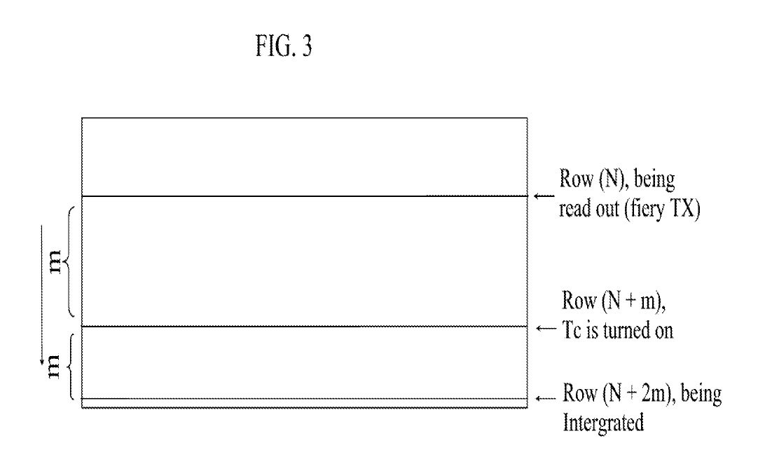

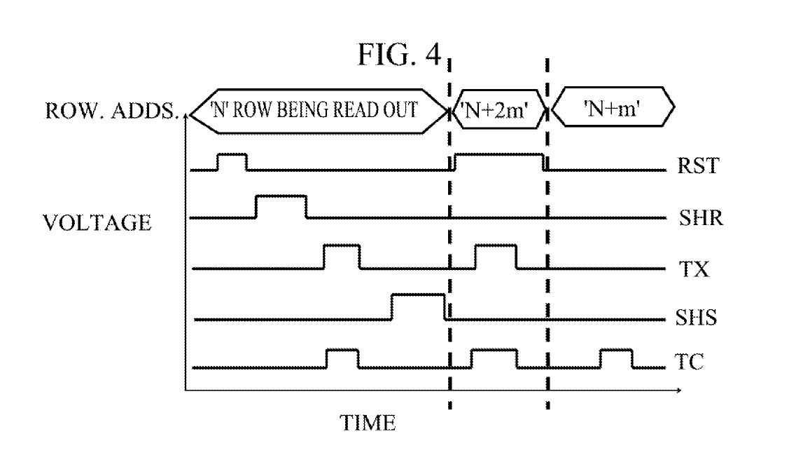

In FIG. 2, a gate 30 is added between the photodiode 12 and the gate 24, and a capacitor 28 is added between the gates 24 and 30. Gate 30 is used to transfer the charge generated by the photodiode to capacitor 28 during the integration time. Capacitor 28 is used to store the charge. Gate 24 is used to transfer this charge to floating diffusion 26. Looking at timing diagram of FIG. 4 and FIG. 3, the charge is transferred to the capacitor 28 from the photodiode only once. However, it can be transferred a multiple number of times and at any time during integration.

Referring to FIG. 3 there is illustration row read out of a full frame in rolling shutter mode (intersection of each row/column is a pixel). In today's architecture, when row N+2m is starting to integrate, row N is being read out and all intermediate 2m rows are being integrated; while in proposed architecture during intermediate time charge from Photodiodes of row N+m is being transferred and stored into capacitor 28 of FIG. 2 via gate 30. For row N, charge from both photodiode and capacitor 28 is transferred to FD with both gate 24 and gate 30 on.

Referring to FIG. 4, there is shown a timing diagram for the circuit of FIG. 2. Looking at FIG. 4, the charge is transferred to capacitor 28 from the photodiode 12 only once, but it can be transferred multiple times or at any time during integration. Timing diagram, FIG. 4 shows that after ‘N’th row readout and ‘N+2m’th row's shutter, ‘N+m’th row's (half way during integration) charge is transferred from the photodiode to the capacitor 28.

With optimized doping and voltages/timing as is well known by a person skilled in the art, the potential gradient can be achieved for easy charge transfer.

While there have been shown and described and pointed out the fundamental novel features of the invention as applied to the preferred embodiments, it will be understood that various omissions and substitutions and changes of the form and details of the apparatus illustrated and in the operation may be done by those skilled in the art, without departing from the spirit of the invention.

What is claimed is:

1. A CMOS pixel circuit for use in digital photography having increased full well comprising:
a photodetector for accumulating photogenerated charge during an integration period;
a reset gate;
a row selector transistor;
a source follower located between said reset gate and said row selector transistor;
a first transfer gate to move a charge from the phodetector to a floating diffusion node located between said transfer gate and said reset gate;
a capacitor located between said photo detector and said first gate; and
a second transfer gate located between said capacitor and said photodetector.

2. The CMOS pixel circuit of claim 1 wherein said second transfer gate transfers the charge from said photodetector to said capacitor.

3. The CMOS pixel circuit of claim 1 wherein said second transfer gate transfers the charge from said photodetector to said capacitor during the integration period.

4. The CMOS pixel circuit of claim 1 wherein said second transfer gate transfers the charge from said photodetector to said capacitor once during the integration period.

5. The CMOS pixel circuit of claim 1 wherein said second transfer gate transfers the charge from said photodetector to said capacitor a multiple number of times during the integration period.

6. The CMOS pixel circuit of claim 1 wherein said second transfer gate transfers the charge from said photodetector to said capacitor at any time during the integration period.

7. The CMOS pixel circuit of claim 1 wherein said second transfer gate transfers the charge from said photodetector to said capacitor during the integration period for storage before being transferred to the first transfer gate.

8. The CMOS pixel circuit of claim 1 wherein said second transfer gate transfers the charge from said photodetector to said capacitor to accumulate at least one charge during the integration period for storage while said photodetector is integrating.

9. The CMOS pixel circuit of claim 1 wherein said second transfer gate transfers the charge from said photodetector to said capacitor for storage during the integration period.

10. The CMOS pixel circuit of claim 1 wherein the charge from said photodetector is stored in a storage means before being transferred to the floating diffusion node.

11. The CMOS pixel circuit of claim 10 wherein said storage means is a capacitor.

12. The CMOS pixel circuit of claim 11 wherein said storage means is a vertical cylinder, a poly-poly cap, a pin diode depletion, a photo diode.

13. A method for increasing full well in a CMOS pixel circuit for use in digital photography comprises:
providing a photodetector for accumulating photogenerated charge during an integration period
providing a source follower located between a reset gate and a row selector transistor;
providing a first transfer gate for moving a charge from the phodetector to a floating diffusion node located between said transfer gate and said reset gate;
providing a storage means for providing extra storage for a charge generated by said photodetector; and
providing a second transfer gate for transferring a charge from said photodetector the said storage means.

14. The method of claim 13 wherein said second transfer gate transfers the charge from said photodetector to said storage means during the integration period.

15. The method of claim 14 wherein said storage means is a capacitor.

16. The method of claim 14 wherein said second transfer gate transfers the charge from said photodetector to said storage means once during the integration period.

17. The method of claim 14 wherein said second transfer gate transfers the charge from said photodetector to said storage means a multiple number of times during the integration period.

18. The method of claim 14 wherein said second transfer gate transfers the charge from said photodetector to said storage means at any time during the integration period.

19. The method of claim 14 wherein said second transfer gate transfers the charge from said photodetector to said storage means during the integration period for storage before being transferred to the first transfer gate.

20. A method for increasing full well in a CMOS pixel circuit for use in digital photography comprises:
providing a photodetector to detect and generate photogenerated charge during an integration period; and
providing timing to transfer and store charge from said photodetector to a place other than said photodetector during an integration period when a charge is being generated at said photodetector.
